(19) United States
(12) Patent Application Publication
(10) Pub. No.: US 2020/0211890 A1
(43) Pub. Date: Jul. 2, 2020

(54) METHOD AND APPARATUS FOR FABRICATING DISPLAY PANEL

(71) Applicants: HKC CORPORATION LIMITED, Shenzhen (CN); CHONGQING HKC OPTOELECTRONICS TECHNOLOGY CO., LTD., Chongqing (CN)

(72) Inventor: Qing WANG, Chongqing (CN)

(21) Appl. No.: 16/632,377

(22) PCT Filed: Dec. 14, 2017
(86) PCT No.: PCT/CN2017/116299

§ 371 Date: Jan. 20, 2020

(30) Foreign Application Priority Data
Jul. 21, 2017 (CN) 201710599737.3

(51) Int. Cl. H01L 21/687; H05K 13/00

(52) U.S. Cl. CPC H01L 21/68721; C23C 14/04; H05K 13/0015

(57) ABSTRACT

A method and an apparatus for fabricating a display panel are provided. The method comprises steps of: providing a substrate; transferring the substrate to a coating chamber; clamping end edge positions of the substrate with clamps; performing a coating operation; and releasing the clamps and transferring the substrate out of the coating chamber. The apparatus comprises a guide rail device for transporting a substrate, and a clamp device for clamping and fixing the substrate, and the guide rail device is movably connected to the clamp device, and the clamp device is provided with clamps for clamping the substrate, and the clamps are placed at positions corresponding to end edges of the substrate. Since the clamps clamp the end edge positions of the substrate, force bearing points can be effectively dispersed, and the substrate can be effectively fixed and its movement limited, effectively preventing the substrate from falling.

### FIELD

The present disclosure relates to the field of display, and particularly to a method and an apparatus of manufacturing a display panel.

### BACKGROUND

Embodiments of the present disclosure include a thin body, power saving, no radiation and so on, and has been widely used. Most displays on the market are backlight displays, which include a display panel and a backlight device. The operation principle of the display panel is to place liquid crystal molecules in between two parallel substrates, and apply a driving voltage on the two substrates to control the rotation direction of the liquid crystal molecules to refract the light of the backlight device to generate a picture.

In particular, due to the low power consumption, excellent picture quality, and high production yield rate and other favorable features, the Thin Film Transistor-Liquid Crystal Display (TFT-LCD) has occupied a dominant position in the display field. Similarly, the TFT-LCD includes a display panel and a backlight device, the display panel includes a color film substrate (CF substrate) and Thin Film Transistor Substrate (TFT Substrate), and transparent electrodes are present on opposite inner sides of the substrate. A layer of liquid crystal (LC) molecules is sandwiched between the two substrates. In the display panel, the orientation of liquid crystal molecules is controlled by an electric field, the polarization state of light is changed, and the light path is penetrate and blocked by a polarizing plate to achieve the purpose of display.

In the manufacturing process of transparent electrode layer of the existing display panel, scratch damage may happen and be concentrated on the four corners of the substrate where broken spots can be formed easily, and the display panel cannot be used continuously. Also, bending deformation can occur due to the influence of heating and gravity, and the substrate and the clamp have difference in expansion coefficient, and the substrate is detached and broken from the clamp, which further adds to the production cost of the display panel.

### SUMMARY

Accordingly, it is necessary to provide a method of manufacturing a display panel that can effectively lower the substrate breakage rate.

A method of manufacturing a display panel, includes: providing a substrate; transferring the substrate to a coating chamber; clamping an edge position of the substrate with a clamp; performing a coating operation; and releasing the clamping by the clamp and transferring the substrate out of the coating chamber.

Further, the step of performing the coating operation includes: setting up an operating temperature of the coating chamber to be between 220° C. and 230° C.; and sputtering a transparent electrode material layer on the substrate.

As such, the operating temperature of the coating chamber is set up to be between 220° C. and 230° C., and the substrate temperature in the process of sputtering a transparent electrode material layer is 120° C.±15° C., and the film forming the sputtering transparent electrode material layer is of favorable performance, which can effectively improve the transparent electrode layer processing level of the display panel, to further improve the display effect of the display panel.

Further, the step of performing a coating operation includes: setting up an operating temperature of the coating chamber to be 220° C.; and sputtering a transparent electrode material layer on the substrate.

As such, setting the working temperature of the coating chamber at 220° C. can effectively avoid the problem of excessive expansion deformation of the substrate.

Further, the clamping position of the clamp is 3 mm to 4 mm from the edge of the substrate. As such, the forces at four corners can be effectively dispersed to the end position of the substrate, to effectively avoid scratch points on the substrate, further reducing the substrate breakage rate, ensuring the yield rate in the production process of the display panel, and effectively reducing the scrap cost of the display panel.

Further, the clamping position of the clamp is 3.5 mm from the edge of the substrate. In this way, it can not only ensure a good clam effect on the substrate, effectively secure and limit the substrate, effectively prevent the substrate from falling, but also effectively avoid the influence of the clamp on the transparent electrode layer, and ensure the yield rate and production efficiency of the display panel.

Further, the clamping position of the clamp is at a middle position of the edge of the substrate. In this way, the clamp is disposed away from the four corners of the substrate, and the forces at the four corners can be effectively dispersed to the edges of the substrate, to effectively avoid scratch points on the substrate, further reducing the substrate breakage rate, and ensuring the yield rate in the production process of the display panel.

According to another embodiment of the present disclosure, the present application further discloses an apparatus of manufacturing a display panel, includes: a guide rail device configured to carry the substrate; and a clamp device configured to clamp and secure the substrate; the guide rail device is movably connected with the clamp device, and the clamp device is provided with a clamp thereon configured to clamp the substrate, and the clamp is arranged at a position corresponding to an edge of the substrate. In this way, the clamp is arranged at the corresponding position of the edge of the substrate. The clamp is configured to clamp the edge position of the substrate, so the forces at the four corners can be effectively dispersed to the edges of the substrate, by which the scratch points on the substrate can be effectively avoided, and the yield rate in the production process of display panel can be ensured.

Further, the clamp device includes a securing frame, the clamp includes a clamp plate, a root portion of the clamp plate is movably connected with the securing frame, a spring is provided between the clamp plate and the securing frame, and the number of turns of the spring is 7 to 11. In this way, the clamp can effectively adapt to different type of substrates, and ensure a better rebound strength of the clamp, so that the clamp cannot easily slack when clamping the substrate, and the elastic reaction is favorable and is not overtighten, to effectively avoid scratch points on the substrate and further reducing substrate breakage rate.

Further, the number of turns of the spring is 9. In this way, more suitable clamping force can be ensured, scratch points can be effectively avoided on the substrate, and the breakage rate of the substrate can be further reduced.

Further, the clamp includes a clamp head, and the clamp head is arranged on the clamp plate, and the thickness of the clamp head is 3 mm to 4 mm. In this way, the substrate can be effectively clamped, a better clamping effect of the clamp can be ensured, scratch points can be effectively avoided on the substrate, and the substrate breakage rate can be further reduced.

Further, the thickness of the clamp is 3.5 mm. In this way, it is possible to ensure a good clam effect of the clamp to the substrate by securing and limiting the substrate effectively and prevent the substrate from falling, and meanwhile avoid the influence of the clamp on the transparent electrode layer, to ensure the yield rate and the production efficiency of the display panel.

Further, the width of one end of the clamp head in contact with the substrate is 4 mm to 6 mm. In this way, the substrate can be effectively clamped with better clamping effect; in addition, more clamping points can be set at the edges of the same length, and the substrate can be effectively clamped and secured.

Further, the width of one end of the clamp head in contact with the substrate is 5 mm. In this way, it is possible to ensure a good clam effect of the clamp to the substrate by securing and limiting the substrate effectively and prevent the substrate from falling, and meanwhile avoid the influence of the clamp on the transparent electrode layer, to ensure the yield rate and the production efficiency of the display panel.

Further, the number of the clamp head provided is two, and the spacing between the two clamp heads is 46 mm to 50 mm. In this way, the elastic force of the spring better acts on the two clamp heads, so that the clamp is not easy to slack when clamping the substrate, and the elastic reaction is favorable and is not overtighten, to effectively avoid scratch points on the substrate and further reducing the substrate breakage rate.

Further, the number of the clamp head provided is two, and the spacing between the two clamp heads is 48 mm. In this way, the size of the clamp can be effectively controlled to ensure that the clamp can effectively clamp the substrate, to facilitate the process of the transparent electrode layer.

Further, the clamp further includes a securing plate, the securing plate is provided with a clamping groove, the clamping plate is provided with a securing hole, screws are used to pass through the securing hole to limit and secure the clamping plate, the clamping plate is arc-shaped, and the tangent of the contact position between the clamp head and the substrate is perpendicular to the plane of the securing frame. In this way, that tangent line of the contact position between the clamp head and the substrate is perpendicular to the plane of the secure frame, so that the clamp head can better secure the substrate, effectively avoid scratch points on the substrate, further reduce the substrate breakage rate, and ensure the yield rate in the production process of the display panel.

According to another embodiment of the present disclosure, the present application further discloses an apparatus of manufacturing a display panel, includes: a guide rail device configured to carry a substrate; and a clamp device configured to clamp and secure the substrate; the guide rail device is movably connected with the clamp device, the clamp device is provided with a clamp thereon configured to clamping a substrate, and the clamp is arranged at a position corresponding to an edge of the substrate; the clamp device includes a securing frame, and the clamp includes a clamp plate, a root portion of the clamp plate is movably connected with the securing frame, a spring is provided between the clamp plate and the securing frame, and a number of turns of the spring is from 7 to 11; the clamp includes a clamp head, the clamp head is arranged on the clamp plate, and a thickness of the clamp head is 3 mm to 4 mm; a width of an end of the clamp head in contact with the substrate is 4 mm to 6 mm; two clamp heads are provided, and a spacing between the two clamp heads is 46 mm to 50 mm; the clamping plate is arranged in the clamping slot, and the securing plate is provided with securing holes through which screws are used to limit and secure the clamping plate, the clamping plate is arc-shaped, and a tangent of a contact position between the clamping head and the substrate is perpendicular to a plane of the securing frame.

Further, the number of turns of the spring is 9, and the width of the end of the clamp head in contact with the substrate is 5 mm; a thickness of the clamp is 3.5 mm; and a spacing between the two clamps is 48 mm.

In the disclosure, by clamping the edge of the substrate with the clamp, the forces at four corner can be effectively dispersed to the edges of the substrate, to effectively prevent scratch points from happening on the substrate, and further reducing the breakage rate of the substrate, ensuring the yield rate in the production process of the display panel, effectively reducing the scrap cost of the display panel, and further improving the market competitiveness of the display panel; also, since the substrate is vulnerable to expansion due to the high temperature in the cavity of the machine, the substrate is likely to fall from the clamp by using the clamp to clamp the four corners of the substrate; by way of clamping the edge position of the substrate, the substrate can be effectively secured and limited, and can be prevented from falling, which can ensure a higher production efficiency of the display panel.

### BRIEF DESCRIPTION OF THE DRAWINGS

FIG. 1 is a flowchart of a method of manufacturing a display panel according to an embodiment of the present disclosure.

FIG. 2 is a flowchart of a method of manufacturing a display panel according to an embodiment of the present disclosure.

FIG. 3 is a schematic diagram of a structure of a display panel according to an embodiment of the present disclosure.

FIG. 4 is a schematic diagram of a structure of a display panel according to an embodiment of the present disclosure.

FIG. 5 is a flowchart of a method of manufacturing a display panel according to an embodiment of the present disclosure.

FIG. 6 is a flowchart of a method manufacturing of a display panel according to an embodiment of the present disclosure.

FIG. 7 is a schematic diagram of a structure of an apparatus of manufacturing according to an embodiment of the present disclosure.

FIG. 8 is a schematic diagram of a structure of an apparatus of manufacturing according to an embodiment of the present disclosure.

### DETAILED DESCRIPTION OF THE EMBODIMENTS

Specific structural and functional details disclosed herein are merely representative for purposes of describing example embodiments. The present disclosure, however, may be embodied in many alternate forms and should not be construed as limited to only the example embodiments set forth herein.

As used herein, spatial or directional terms, such as “left”, “right”, “inner”, “outer”, “above”, “below”, “top”, “bottom”, and the like, are understood to encompass various alternative orientations and, accordingly, such terms are not to be considered as limiting.

It will be understood that, although the terms first, second, etc. may be used herein to describe various elements, these elements should not be limited by these terms. These terms are only used to distinguish one element from another. Thus, a first element could be termed a second element without departing from the teachings of the present disclosure.

The terms “first,” “second,” “third,” “fourth,” and the like in the description and the claims, if any, may be used for distinguishing between similar elements and not necessarily for describing a particular sequential or chronological order. It is to be understood that the terms so used are interchangeable under appropriate circumstances and the embodiments of the disclosure described herein are, for example, operation in sequences other than those illustrated or otherwise described herein. Furthermore, the terms “comprise,” “include,” “have” and any variations thereof, are intended to cover non-exclusive inclusions, and a process, method, article, or apparatus that comprises a list of elements is not necessarily limited to those elements, but may include other elements not expressly listed or inherent to such process, method, article, or apparatus.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The present disclosure will now be further described with reference to the accompanying drawings and embodiments.

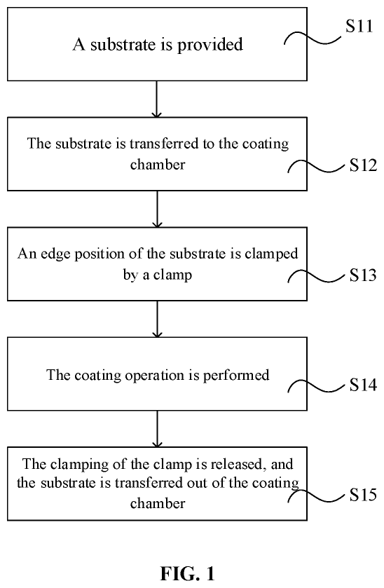

As shown in FIG. 1, a method of manufacturing a display panel includes the following steps:

At S11: a substrate is provided;

At S12: the substrate is transferred to the coating chamber;

At S13: an edge position of the substrate is clamped by a clamp;

At S14: the coating operation is performed;

At S15: the clamping of the clamp is released, and the substrate is transferred out of the coating chamber.

An active switch is formed on a substrate. In the process forming the transparent electrode layer, an edge position of the substrate is clamped by a clamp 23, the force can be effectively dispersed by clamping the clamp 23 on the edge position of the substrate. The forces at four corners can be dispersed to the edges of the substrate, to effectively prevent scratch points from happening on the substrate, and further reducing the breakage rate of the substrate, ensuring the yield rate in the production process of the display panel, effectively reducing the scrap cost of the display panel, and further improving the market competitiveness of the display panel. Also, since the substrate is vulnerable to expansion due to the high temperature in the cavity of the machine, and using the clamp 23 to clamp the four corners of the substrate, the substrate is likely to fall from the clamp 23, by way of clamping the edge position of the substrate, the substrate can be effectively secured and limited, the substrate is effectively prevented from falling, and a higher production efficiency of the display panel is ensured.

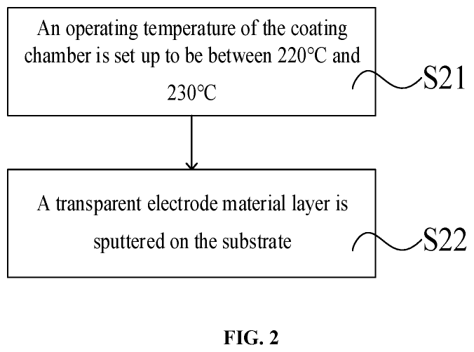

As shown in FIG. 2, the step the coating operation is performed includes:

At S21: an operating temperature of the coating chamber is set up to be between 220° C. and 230° C.;

At S22: a transparent electrode material layer is sputtered on the substrate.

The operating temperature is set up to be between 220° C. and 230° C., and the substrate temperature is 120° C.±15° C. in the process of sputtering the transparent electrode material layer, the performance of the film forming the sputtered transparent electrode material lay is favorable, the manufacturing process level of the transparent electrode layer of the display panel can be effectively improved, and the display performance of the display panel is further improved. A transparent electrode material layer is sputtered on the active switch, then the transparent electrode material layer is exposed and developed, a pattern of the transparent electrode layer is obtained on the transparent electrode material layer, and the transparent electrode layer is obtained by etching. The operating temperature is selected to be 220° C., so that the problem of excessive expansion deformation of the substrate can be effectively avoided, to effectively secure and limiting the substrate, effectively preventing the substrate from falling, ensuring higher production efficiency of the display panel, and effectively reducing the breakage rate of the substrate, ensuring the yield rate in the production process of the display panel, effectively reducing the scrap cost of the display panel, and further improving the market competitiveness of the display panel.

The clamping position of the clamp 23 is 3 mm to 4 mm from the edge of the substrate. Clamping the clamp 23 at 3 mm to 4 mm from the edge of the substrate makes the forces at four corners to be effectively dispersed to the edges of the substrate, to effectively avoid scratch points on the substrate and further reducing the substrate breakage rate. The yield rate in the production process of the display panel is ensured, and the scrap cost of the display panel is effectively reduced. Clamping the clamp 23 at 3 mm to 4 mm from the edge of the substrate can not only ensure a good clamping effect on the substrate and effectively securing and limiting the substrate and effectively preventing the substrate from falling, but can also effectively avoid the influence of the clamp 23 on the process of the transparent electrode layer, the yield rate and production efficiency of the display panel are ensured.

The clamping position of the clamp 23 is in the middle of the edge of the substrate, and the clamp 23 is positioned away from the four corners of the substrate, so that the forces of the four corners can be effectively dispersed to the edges of the substrate, to effectively avoid scratch points on the substrate, further reducing the substrate breakage rate, ensuring the yield rate in the production process of the display panel, effectively reducing the scrap cost of the display panel. A plurality of the clamps 23 are evenly spaced at each edge of the substrate, to more effectively disperse the force of the substrate, effectively avoid scratch points on the substrate, and further reducing the substrate breakage rate. Clamping the clamp 23 at a position more than 10 cm from the corner position of the substrate can effectively disperse the force of the substrate, and effectively avoid the scratch point on the substrate.

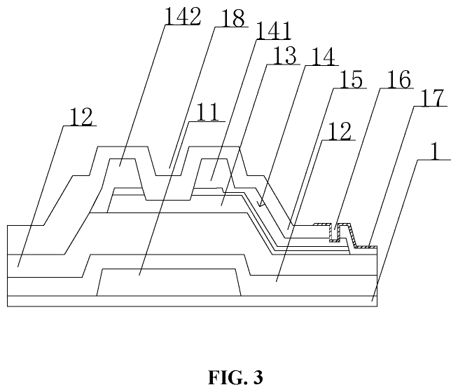

As shown in FIG. 3, the active switch includes a metal layer and a protective layer, the metal layer includes a first metal layer 11 and a second metal layer 14, the protective layer includes a first protective layer 12 and a second protective layer 15, the first metal layer 11 is arranged on the substrate 1, the first protective layer 12 is arranged on the first metal layer 11, the second metal layer 14 is arranged on the first protective layer 12, and the second protectively layer 15 is arranged on the second metal layer 14. The second metal layer 14 includes a source layer 141 and a drain layer 142 and a channel 18 provided therebetween. A semiconductor layer 13 is arranged at the bottom of the channel 18, the metal layer can be effectively protected through the protection by the first protective layer 12 and the second protective layer 15, further avoiding oxidation of the surface of the metal layer. When a defective area of the display panel is to be re-processed, the protectively layer can effectively prevent the metal layer of the display panel from being directly corroded by the washing agent, so that the metal layer can be kept intact to avoid wire breakage. The success rate of the re-processing of the display panel is increased and the scrap cost is reduced. The edge of the metal layer, in microstructure, always show metal burrs. By providing the first protective layer 12 and the second protective layer 15, the metal burrs on the metal layer can be better covered, and the metal burrs can be effectively prevented from being exposed outside the protective layer, so that the protective layer can better protect the metal layer. Also, the use of the protective layer can very well re-process and repair the problematic area without scrapping the thin film transistor array substrate, which is more environment-friendly.

The protective layer is a silicon oxide layer, that is, the protective layer is made of a silicon oxide material, and hydrogen ions are used to bombard the metal layer before the silicon oxide is deposited on the metal layer by chemical vapor deposition (CVD) technology. The problem of surface oxidation of the metal layer can be effectively addressed. The metal oxide can be reduced to metal by hydrogen ion oxidation-reduction reaction, and the problem that the waiting time between the metal layer process and the protective layer process is too short can be effectively addressed. After a CVD is performed on the metal layer, the first silicon oxide layer is waited to be cooled and solidified to form a first layer of the first protective layer 12 which, after the second CVD, forms a second layer of the first protective layer 12. The foregoing steps are repeated so that at least two silicon oxide layers are deposited on the metal layer to better cover the metal layer to effectively preventing the metal burr from being exposed outside the protective layer. Thus, the protective layer can better protect the metal layer. The chemical property of the silicon oxide is stable and will not react with the potassium hydroxide solution and therefore can effectively avoid a corrosion destruction of the metal layer by the washing agent and well protect the metal layer. In addition, at least two silicon oxide layers are formed by performing multiple CVDs, no additional raw materials need to be replaced halfway, no additional equipment need to be replaced, so that raw materials cost and storage cost are reduced. No new materials need to be added to the material list and can well control the amount of silicon oxide used, which further reduce the production and manufacturing costs, so that the display panel has a stronger market competitiveness. Of course, the second protective layer 15 may be provided in two layers in the same manner.

The protective layer is of course be a silicon nitride layer, that is, the protective layer is made of a silicon nitride material, and hydrogen ions are used to bombard the metal layer before the silicon oxide is deposited on the metal layer by the CVD technology. The problem of surface oxidation of the metal layer can be effectively addressed. The metal oxide can be reduced to metal by hydrogen ion oxidation-reduction reaction, and the problem that the waiting time between the metal layer process and the protective layer process is too short can be effectively addressed. After a CVD is performed on the metal layer, the first silicon nitride layer is waited to be cooled and solidified to form a first layer of the first protective layer 12 which, after the second CVD, forms a second layer of the first protective layer 12. The foregoing steps are repeated so that at least two silicon nitride layers are deposited on the metal layer to better cover the metal layer to effectively preventing the metal burr from being exposed outside the protective layer. So that the protective layer can better protect the metal layer. The silicon nitride is a super-hard material, and the silicon nitride material is wear-resistant, oxidation resistant under high temperature, as well as cold-hot impact resistant. In addition, at least two silicon nitride layers are formed by performing multiple CVDs, no additional raw materials need to be replaced halfway, no additional equipment need to be replaced, so that raw materials cost and storage cost are reduced. No new materials need to be added to the material list and can well control the amount of silicon oxide used, which further reduce the production and manufacturing costs, so that the display panel has a stronger market competitiveness. Of course, the second protective layer 15 may be provided in two layers in the same manner.

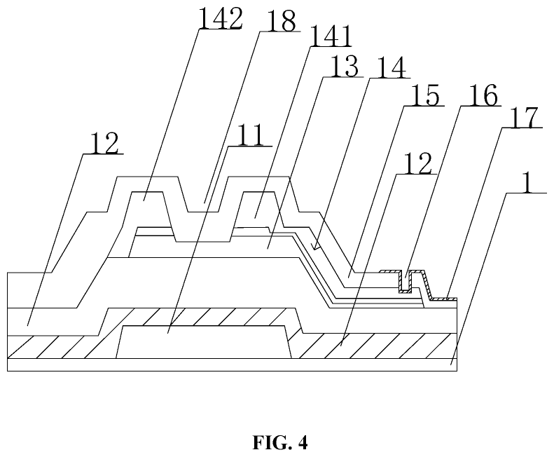

As illustrated in FIG. 4, as another embodiment of the present disclosure, the protective layer includes a silicon nitride layer and a silicon oxide layer. Before the silicon oxide is deposited on the metal layer by the CVD technology, hydrogen ions are used to bombard the metal layer. The problem of surface oxidation of the metal layer can be effectively addressed. The metal oxide is reduced to metal by hydrogen ion oxidation-reduction reaction, and the problem that the waiting time between the metal layer process and the protective layer process is too short can be effectively addressed. Then the silicon oxide is deposited on the metal layer by CVD technology and wait for the silicon oxide layer to cool and solidify to form the first layer of the first protective layer 12. Then the CVD is applied to deposit silicon nitride on the silicon oxide layer to form a second layer of the first protective layer 12. Of course, it can also be that the silicon nitride layer is provided as the first layer of the first protective layer 12, and by stacking the silicon nitride layer and the silicon oxide layer, the protective layer can be better attached to the metal layer, the metal burrs on the metal layer can be better covered, the metal burrs can be effectively prevented from being exposed outside the protective layer, the metal layer can be better protected by the protective layer. A direct corrosion of the metal layer of the liquid crystal panel by the washing agent can be effectively avoided, so that the metal layer can be kept intact to avoid the problem of wire breakage. The durability of the display panel is further improved. Similarly, the second protective layer 15 may be prepared with two layers by stacking the silicon nitride layer and the silicon oxide layer.

A transparent electrode layer 17 is formed on the second protective layer 15, an opening 16 is provided on the second protective layer 15, the transparent electrode layer 17 is connected with the second metal layer 14 through the opening 16. The second protective layer 15 is provided with the opening 16 to facilitate connection between the transparent electrode layer 17 and the second metal layer 14 to ensure a good display effect of the display panel. The second metal layer 14 at the opening 16 is bombarded with hydrogen ions before the transparent electrode layer 17 is provided. The problem of surface oxidation of the second metal layer 14 can be effectively addressed. The metal oxide on the second metal layer 14 is reduced to metal by the oxidation-reduction reaction of the hydrogen ions, and the problem that the waiting time between the second metal layer 14 process and the transparent electrode layer 17 process is too short can be effectively addressed. Then, the transparent electrode layer 17 is arranged on the bombarded second metal layer 14, and the transparent electrode layer 17 can effectively protect the second metal layer 14 at the opening 16 and further prevent oxidation of the surface of the metal layer.

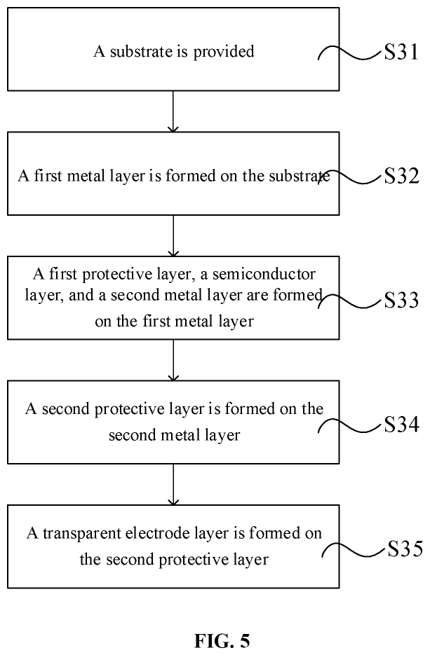

As shown in FIG. 5, a method of manufacturing a display panel includes the following steps:

At S31: a substrate is provided;

At S32: a first metal layer is formed on the substrate;

At S33: a first protective layer, a semiconductor layer, and a second metal layer are formed on the first metal layer;

At S34: a second protective layer is formed on the second metal layer;

At S35: a transparent electrode layer is formed on the second protective layer.

In the first mask process, the substrate 1 is first cleaned, the first metal material layer is sputtered on the cleaned substrate 1; after the completion of the first metal material layer sputtering, a cleaning is performed before the film formation. Then the photoresist is coated on the cleaned first metal material layer, the photoresist is aligned and exposed by the first mask. A pattern of the first metal layer 11 is obtained by developing the first metal material layer with a developing solution. Then the first metal material layer is etched with an etching solution to obtain the first metal layer 11, and the residual photoresist is removed, and the first mask process inspection is completed.

In the second mask process, the substrate 1 completed with the first mask process is cleaned first; on the first metal layer 11, the first protective layer 12 is deposited on the first metal layer 11 through the CVD technology, and a semiconductor material layer is formed on the cleaned first protective layer 12. After completing sputtering of the semiconductor material layer, the cleaning is performed before the film formation. Then a second metal material layer is formed on the cleaned semiconductor material layer, the photoresist is coated on the cleaned second metal material layer. The photoresist is aligned and exposed with a second mask. The pattern of the second metal layer 14 is obtained developing the second metal material with the developing solution. Then the semiconductor layer is etched with the etching solution to obtain the second metal layer 14. The photoresist is aligned and exposed with the second mask, the pattern of the semiconductor layer 13 is obtained by developing the semiconductor material layer. Then the semiconductor material layer is dry-etched to obtain the semiconductor layer 13, the residual photoresist is removed, and the second mask process inspection is completed.

In the third mask process, the substrate 1 completed with the second mask process is cleaned first, and a second protective material layer is formed on the cleaned second metal layer 14. The photoresist is coated on the second metal material layer, and the photoresist is aligned and exposed by a fourth mask. A pattern of the second protective layer 15 is obtained by developing the second protective material layer with the developing solution. Then the second protective material layer is etched with the etching solution to obtain the second protective layer 15, the residual photoresist is removed, and the third mask process inspection is completed.

In the fourth mask process, the substrate 1 completed with the third mask process is cleaned first, and a transparent electrode material layer is formed on the cleaned second protective layer 15. The photoresist is coated on the transparent electrode material layer, and the photoresist is aligned and exposed by a fifth mask. A pattern of the transparent electrode layer 17 is obtained by developing the transparent electrode material layer with the developing solution. Then the transparent electrode material layer is etched with the etching solution to obtain the transparent electrode layer 17, the residual photoresist is removed, and the fourth mask process inspection is completed.

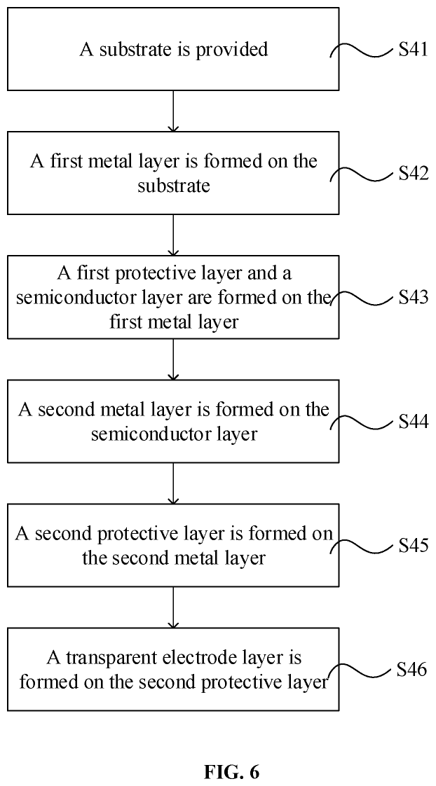

As shown in FIG. 6, the manufacturing method of the display panel comprises the following steps:

At S41: a substrate is provided;

At S42: a first metal layer is formed on the substrate;

At S43: a first protective layer and a semiconductor layer are formed on the first metal layer;

At S44: a second metal layer is formed on the semiconductor layer;

At S45: a second protective layer is formed on the second metal layer;

At S46: a transparent electrode layer is formed on the second protective layer.

In the first mask process, the substrate 1 is first cleaned, the first metal material layer is sputtered on the cleaned substrate 1; after the completion of the first metal material layer sputtering, a cleaning is performed before the film formation. Then the photoresist is coated on the cleaned first metal material layer, and the photoresist is aligned and exposed by the first mask. A pattern of the first metal layer 11 is obtained by developing the first metal material layer with a developing solution. Then the first metal material layer is etched with an etching solution to obtain the first metal layer 11, and the residual photoresist is removed, and the first mask process inspection is completed.

In the second mask process, the substrate 1 competed with the first mask process is cleaned first, on the first metal layer 11, the first protective layer 12 is deposited on the first metal layer 11 through the CVD technology, and a semiconductor material layer is formed on the cleaned first protective layer 12. After completing sputtering of the semiconductor material layer, a cleaning is performed before the film formation. The photoresist is coated on the cleaned semiconductor material layer. The photoresist is aligned and exposed with a second mask. The pattern of the second semiconductor layer 13 is obtained by developing the semiconductor material layer with the developing solution. Then the semiconductor material layer is etched with the etching solution to obtain the semiconductor layer 13. The residual photoresist is removed, and the second mask process inspection is completed.

In the third mask process, the substrate 1 completed with the second mask process is cleaned first, and a second metal material layer is formed on the cleaned semiconductor layer 13. After completing sputtering of the second metal material layer, a cleaning is performed before the film formation. The photoresist is coated on the cleaned second metal material layer, the photoresist is aligned and exposed by a third mask. A pattern of the second metal layer 14 is obtained by developing the second metal material layer with the developing solution. And then the second protective material layer is etched with the etching solution to obtain the second protective layer 15, the residual photoresist is removed, and the third mask process inspection is completed.

In the fourth mask process, the substrate 1 completed with the third mask process is cleaned first, and a second protective material layer is formed on the cleaned second metal layer 14. The photoresist is coated on the second metal material layer, and the photoresist is aligned and exposed by a fourth mask. A pattern of the second protective layer 15 is obtained by developing the second protective material layer with the developing solution. And then the second protective material layer is etched with the etching solution to obtain the second protective layer 15, the residual photoresist is removed, and the fourth mask process inspection is completed.

In the fifth mask process, the substrate 1 completed with the fourth mask process is cleaned first, a transparent electrode material layer is formed on the cleaned second protective layer 15. The photoresist is coated on the transparent electrode material layer, and the photoresist is aligned and exposed by a fifth mask. A pattern of the transparent electrode layer 17 is obtained by developing the transparent electrode material layer with a developing solution. Then the transparent electrode material layer is etched with the etching solution to obtain the transparent electrode layer 17, the residual photoresist is removed, and the fourth mask process inspection is completed.

In particular embodiments, the display panel includes a substrate, an active switch is formed on the substrate, and a transparent electrode layer is formed on the active switch. The active switch includes a first metal layer, a first protective layer and a semiconductor layer are formed on the first metal layer. A second metal layer is formed on the semiconductor layer, a second protective layer is formed on the second metal layer, and a transparent electrode layer is formed on the second protective layer.

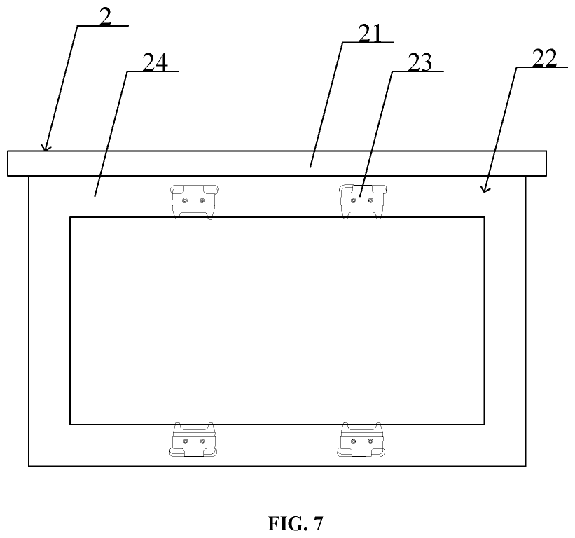

As shown in FIG. 7, according to another embodiment of the present disclosure, the present disclosure further discloses an apparatus 2 of manufacturing a display panel, includes:

a guide rail device 21 configured to carry the substrate; and

a clamp device 22 configured to clamp and secure the substrate;

the guide rail device 21 is movably connected with the clamp device 22, the clamp device 22 is provided with a clamp 23 thereon configured to clamp the substrate, and the clamp 23 is arranged at a position corresponding to an edge of the substrate.

The guide rail device 21 is configured to effectively transport the substrate. The guide rail device 21 includes the guide rail, which is driven by electromagnetic force to effectively ensure the transportation stability of the substrate, and further avoid the influence of the vibration caused by the uneven guide rail on the substrate. The clamp device 22 can effectively clamp and secure the substrate, further prevent the substrate from falling from the clamp device 22. Setting the clamp 23 at the corresponding position at the edge of the substrate and clamping the clamp 23 at the edge of the substrate can effectively disperse the forces at the four corners to the edge of the substrate, to effectively prevent scratch points from happening on the substrate, and further reducing the breakage rate of the substrate, ensuring the yield rate in the production process of the display panel, effectively reducing the scrap cost of the display panel, and further improving the market competitiveness of the display panel.

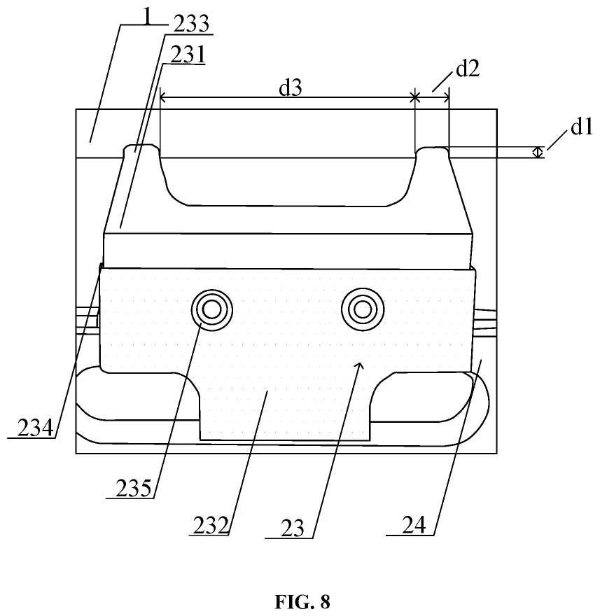

As shown in FIG. 8, the clamp device 22 includes a securing frame 24, and the clamp 23 includes a clamp plate 231 having a root portion movably connected to the securing frame 24. A spring is arranged between the clamp plate 231 and the securing frame 24. The number of turns of the spring is 7 to 11, the clamping force of the spring is related to the strength of the spring. The turns of the spring is 7 to 11, the number of the turns of the spring is selected according to the thicknesses of different substrates, so that the clamp 23 can effectively adapt to different types of substrates, and better rebound strength of the clamp 23 is ensured. In this way the clamp 23 is not easily slacked when clamping the substrate, and the elastic reaction is favorable and not overtighten, to effectively avoid scratch points on the substrate, and further reducing the substrate breakage rate. The use of a 9-ring spring can ensure a more appropriate clamping force and effectively avoid scratch points on the substrate, and to reduce the substrate breakage rate.

The clamp 23 includes a clamp head 233, the clamp head 233 is arranged on the clamp plate 231, and the thickness of the clamp head 233 is 3 mm to 4 mm. As shown by d1 in FIG. 8, the thickness of the clamp head 233 is 3 mm to 4 mm to effectively avoid scratch points on the substrate, and to reduce the substrate breakage rate, ensuring the yield rate in the production process of the display panel, and effectively reducing the scrap cost of the display panel. The thickness of the clamp 23 is set up to be 3.5 mm, so that the clamp 23 can ensure good clamping effect on the substrate, effectively secure and limit the substrate, effectively prevent the substrate from falling, and effectively avoid the influence of the clamp 23 on the transparent electrode layer, and the yield rate and production efficiency of the display panel are ensured. Also, the thickness of the clamp head 233 is between 3 mm and 4 mm, which ensures a larger contact area between the clamp head 233 and the substrate, to make the clamping more stable.

The width of the end of the clamp head 233 in contact with the substrate is 4 mm to 6 mm. As shown by d2 in FIG. 8, the width of the end of the clamp head 233 in contact with the substrate is 4 mm to 6 mm, to effectively clamp the substrate, and ensure that the clamp 23 can better clamp the substrate. More clamping points can be set at the edges of the same length, and the substrate can be thus effectively clamped and secured. In one embodiment, the width can be set up to be 5 mm, so that a better clamping effect of the clamp 23 on the substrate can be ensured, the substrate can be effectively secured and limited, and the substrate can be effectively prevented from falling. It is also possible to effectively avoid the influence of the clamp 23 on the transparent electrode layer formation, ensuring the yield rate and the production efficiency of the display panel.

The number of the clamp head 233 provided is two, the distance between the two clamp heads 233 is 46 mm to 50 mm, as shown in d3 in FIG. 8, so that the spring return force can better act on the two clamp heads 233, the clamp 23 is not easily slacked when clamping the substrate, and the elastic reaction is favorable and the clamping is not overtightened. Thus, scratch points on the substrate can be effectively avoided, and the substrate breakage rate can be further reduced. In one embodiment, the distance between the two clamp heads 233 is set up to be 48 mm, the size of the clamp 23 can be effectively controlled, and the clamp 23 can effectively clamp the substrate, to facilitate the transparent electrode layer manufacturing process.

The clamp 23 further includes a securing plate 232, the securing plate 232 is provided with a locking slot 234, the clamping plate 231 is provided in the locking slot 234, and the securing plate 232 is provided with a securing hole 235. The clamping plate 231 is arc-shaped, and the tangent line of the contact position between the clamp head 233 and the substrate is perpendicular to the plane of the securing frame 24. The securing plate 232 can effectively limit and secure the clamping plate 231, and the securing plate 232 can be well secured on the securing frame 24 to ensure a favorable clamping effect of the clamp 23 to the substrate. The clamping groove 234 is arranged to facilitate the securing of the clamping plate 231. The locking slot 231 is provided to facilitate the securing of the clamp plate 231, and the clamp plate 231 is limited and secured by screws through the securing holes 235. The transparent electrode layer is processed on substrates of different sizes, it is easier to replace with a more appropriate model of clamp plate 231, and the production efficiency of the display panel is improved. The arc-shaped clamping plate 231 facilitates clamping of the substrate by the clamp 23, so that the clamping is more stable. The tangent of the contact position between the clamp head 233 and the substrate is perpendicular to the plane of the securing frame 24, so that the clamp head 233 can better secure the substrate and effectively avoid scratch points on the substrate, to reduce the substrate breakage rate, ensuring the yield rate in the production process of the display panel, and effectively reducing the scrap cost of the display panel.

In some embodiment, the display panel is, for example, a liquid crystal panel, an organic light-emitting diode (OLED) panel, a quantum dot light emitting diode (QLED) panel, a plasma panel flat panel, curved surface panel, etc.

Although the invention is illustrated and described herein with reference to specific embodiments, the invention is not intended to be limited to the details shown. Rather, various modifications may be made in the details within the scope and range of equivalents of the claims and without departing from the invention. Therefore, the protection scope of the present invention shall be subject to the protection scope of the appended claims.

1. A method of manufacturing a display panel, comprising:
providing a substrate;
transferring the substrate to a coating chamber;
clamping an edge position of the substrate with a clamp;
performing a coating operation; and
releasing the clamping by the clamp and transferring the substrate out of the coating chamber.

2. The method of manufacturing a display panel according to claim 1, wherein the step of performing the coating operation comprises:
setting up an operating temperature of the coating chamber to be between 220° C. and 230° C.; and
sputtering a transparent electrode material layer on the substrate.

3. The method of manufacturing a display panel according to claim 1, wherein the step of performing a coating operation comprises:
setting up an operating temperature of the coating chamber to be 220° C.; and
sputtering a transparent electrode material layer on the substrate.

4. The method of manufacturing a display panel according to claim 1, wherein a clamping position of the clamp is 3 mm to 4 mm from the edge position of the substrate.

5. The method of manufacturing a display panel according to claim 1, wherein a clamping position of the clamp is 3.5 mm from the edge position of the substrate.

6. The method of manufacturing a display panel according to claim 1, wherein a clamping position of the clamp is in a middle of the edge position of the substrate.

7. An apparatus of manufacturing a display panel, comprising:
a guide rail device configured to carry a substrate; and
a clamp device configured to clamp and secure the substrate;
wherein the guide rail device is movably connected with the clamp device, the clamp device is provided with a clamp thereon configured to clamp the substrate, and the clamp is arranged at a position corresponding to an edge of the substrate.

8. The apparatus of manufacturing a display panel according to claim 7, further comprising a clamp apparatus which comprises a securing frame, and the clamp comprises a clamp plate, and a root portion of the clamp plate is movably connected with the securing frame.

9. The apparatus of manufacturing a display panel according to claim 8, wherein a spring is provided between the clamp plate and the securing frame.

10. The apparatus of manufacturing a display panel according to claim 9, wherein a number of turns of the spring is 7 to 11.

11. The apparatus of manufacturing a display panel according to claim 9, wherein a number of turns of the spring is 9.

12. The apparatus of manufacturing a display panel according to claim 8, wherein the clamp comprises a clamp head provided on the clamp plate, and a thickness of the clamp head is 3 mm to 4 mm.

13. The apparatus of manufacturing a display panel according to claim 8, wherein a thickness of the clamp is 3.5 mm.

14. The apparatus of manufacturing a display panel according to claim 12, wherein a width of an end of the clamp head in contact with the substrate is 4 mm to 6 mm.

15. The apparatus of manufacturing a display panel according to claim 12, wherein a width of an end of the clamp head in contact with the substrate is 5 mm.

16. The apparatus of manufacturing a display panel according to claim 12, wherein two clamp heads are provided, and a spacing between the two clamp heads is 46 mm to 50 mm.

17. The apparatus of manufacturing a display panel according to claim 12, wherein two clamp heads are provided, and a spacing between the two clamp heads is 48 mm.

18. An apparatus of manufacturing a display panel, comprising:
a guide rail device configured to carry a substrate; and
a clamp device configured to clamp and secure the substrate;
wherein the guide rail device is movably connected with the clamp device, the clamp device is provided with a clamp thereon configured to clamping a substrate, and the clamp is arranged at a position corresponding to an edge of the substrate; the clamp device comprises a securing frame, the clamp comprises a clamp plate, a root portion of the clamp plate is movably connected with the securing frame, a spring is provided between the clamp plate and the securing frame, and a number of turns of the spring is from 7 to 11; the clamp comprises a clamp head, the clamp head is arranged on the clamp plate, and a thickness of the clamp head is 3 mm to 4 mm; a width of an end of the clamp head in contact with the substrate is 4 mm to 6 mm; a number of the clamp head provided is two, and a spacing between every two clamp heads is 46 mm to 50 mm; the clamping plate is arranged in a clamping slot, and a securing plate is provided with securing holes through which screws are used to limit and secure the clamping plate; the clamping plate is arc-shaped, and a tangent of a contact position between the clamping head and the substrate is perpendicular to a plane of the securing frame.

19. The apparatus of manufacturing a display panel according to claim 18, wherein the number of turns of the spring is 9, and the width of the end of the clamp head in contact with the substrate is 5 mm.

20. The apparatus of manufacturing a display panel according to claim 18, wherein a thickness of the clamp is 3.5 mm and a spacing between every two clamps is 48 mm.
